(19) United States
(12) Patent Application Publication
(10) Pub. No.: US 2017/0363666 A1
(43) Pub. Date: Dec. 21, 2017

(54) METHOD AND APPARATUS FOR ENERGY FLOW VISUALIZATION

(71) Applicant: Enphase Energy, Inc., Petaluma, CA (US)

(72) Inventors: Mohammad Alkuran, Santa Rosa, CA (US); Casey John Russell Blair, Novato, CA (US); Chris Eich, Sebastopol, CA (US); Benoît Menendez, Penngrove, CA (US)

(21) Appl. No.: 15/623,969

(22) Filed: Jun. 15, 2017

Related U.S. Application Data
(60) Provisional application No. 62/351,060, filed on Jun. 16, 2016.

(51) Int. Cl. G01R 21/133; H02J 13/00; H02J 3/38; G06F 3/14; H02S 50/00; G06T 11/20

(52) U.S. Cl. CPC G01R 21/133; H02J 3/381; G06F 3/14; H02J 13/0006; G06T 11/206; H02S 50/00

(57) ABSTRACT

A method and apparatus for visualizing energy flows. In one embodiment, the method comprises (I) obtaining a plurality of measured energy flow values for a plurality of energy flows between a plurality of energy sources and a plurality of energy sinks, wherein at least one of measured energy flow value is a measurement of energy flow from an energy source to two or more energy sinks; (II) computing a plurality of energy flow values based on the measured energy flow values and a set of energy priority allocation rules, wherein each computed energy flow value of the plurality of energy flow values represents energy flow between an energy source of the plurality of energy sources and an energy sink of the plurality of energy sinks; and (III) generating a display image representing at least one computed energy flow value of the plurality of energy flow values.

### CROSS-REFERENCE TO RELATED APPLICATIONS

This application claims benefit of U.S. provisional patent application Ser. No. 62/351,060, entitled “Energy Flow Calculations”, and filed Jun. 16, 2016, which is herein incorporated in its entirety by reference.

### BACKGROUND OF THE INVENTION

### Field of the Invention

Embodiments of the present disclosure relate generally to determining energy flow information and, more particularly, to presenting a visualization of the energy flow information pertaining to a distributed energy resource (DER).

### Description of the Related Art

As the electricity grid continues to modernize, the use of distributed energy resources (DERs) to produce energy from renewable resources and to provide energy storage is rapidly increasing. Energy produced by a DER's renewable resources may be used by one or more loads, stored for later use, and/or coupled to a larger grid such as a commercial power grid. The combination of the commercial grid, a DER, and a locale (such as a home or business) coupled to a DER provides a variety of both energy sources and energy recipients that varies over time; for example, a solar power system of the DER may provide sufficient energy on sunny days to power a home's loads and also store additional energy in a battery bank, while during evening hours the loads receive energy from the commercial grid. In order for an operator of the DER (such as a homeowner) to evaluate system operation and efficiencies, it is necessary to understand the various flows of energy between the energy sources and the energy recipients.

Therefore, there is a need in the art for providing a visualization of energy flow between energy sources and energy recipients in a readily understandable format.

### SUMMARY OF THE INVENTION

Embodiments of the present invention generally relate to visualizing energy flows substantially as shown in and/or described in connection with at least one of the figures, as set forth more completely in the claims.

Various advantages, aspects and novel features of the present disclosure, as well as details of an illustrated embodiment thereof, will be more fully understood from the following description and drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a block diagram of a system for energy generation and consumption in accordance with one or more embodiments of the present invention;

FIG. 2 is a block diagram of a power conditioner controller in accordance with one or more embodiments of the present invention;

FIG. 3 is a block diagram of a DER controller in accordance with one or more embodiments of the present invention;

FIG. 4 is a block diagram of a master controller in accordance with one or more embodiments of the present invention;

FIG. 5 is a block diagram depicting energy sources and sinks of the system and corresponding computed energy flows in accordance with one or more embodiments of the present invention;

FIG. 6 is a plurality of tables for a rolling time series in accordance with one or more embodiments of the present invention;

FIG. 7 is a representation of displays for energy flow visualization for the system 100 in accordance with one or more embodiments of the present invention; and

FIG. 8 is a flow diagram of a method for energy flow visualization in accordance with one or more embodiments of the present invention.

### DETAILED DESCRIPTION

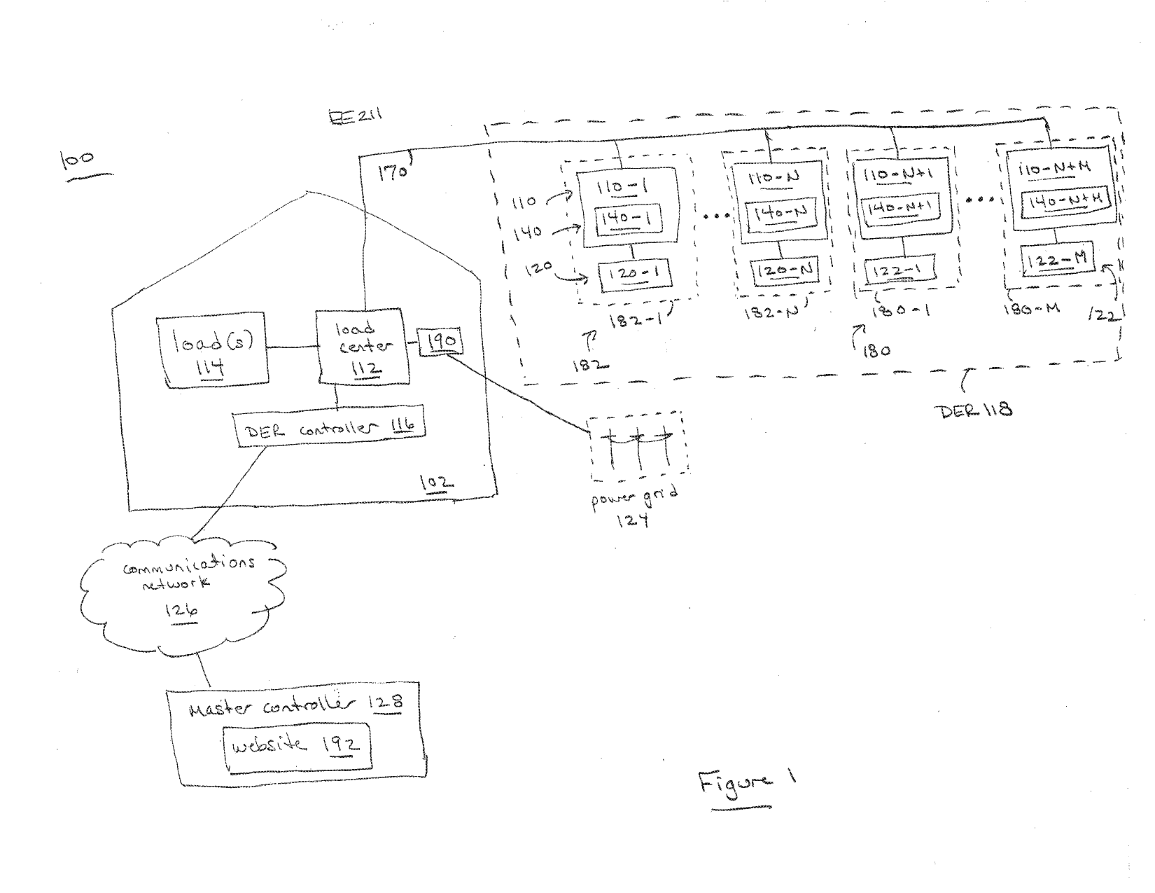

FIG. 1 is a block diagram of a system 100 for energy generation and consumption in accordance with one or more embodiments of the present invention. This diagram only portrays one variation of the myriad of possible system configurations. The present invention can function in a variety of environments and systems for visualizing energy flow.

The system 100 comprises a locale 102, such as a residential or commercial building, coupled to a distributed energy resource (DER) 118 and a power grid 124 (e.g., a commercial power grid). The DER 118 can both generate alternating current (AC) power as well as store energy for later use, as described in detail below. Although the DER 118 is depicted as situated outside of the locale 102, in some other embodiments one or more components of the DER 118 may reside within the locale 102.

The locale 102 comprises a load center 112 coupled to the DER 118 via a bus 170, to the power grid 124, to one or more loads 114 (e.g., appliances and the like), and to a DER controller 116. The load center 112 couples the AC power generated by the DER 118 to the loads 114 and/or to the power grid 124. A meter 190 is coupled between the load center 112 and the power grid 124 for measuring the net energy from the power grid 124. The measured net energy may then be communicated from the meter 190 to the DER controller 116 (e.g., via power line communication).

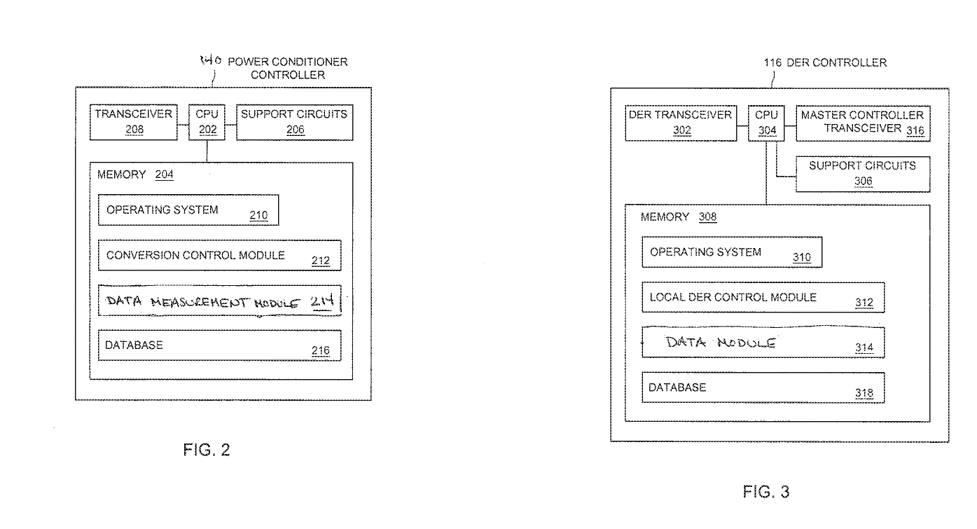

The DER 118 comprises power conditioners 110-1 . . . 110-N, . . . 110-N+M (collectively referred to as power conditioners 110) coupled in parallel to the bus 170. Each of the power conditioners 110 comprises a controller 140, described below with respect to FIG. 2, for controlling the corresponding power conditioner 110.

As shown in FIG. 1, the power conditioners 110-1 . . . 110-N are coupled to direct current (DC) energy sources 120-1 . . . 120-N, respectively, to form DER generators 182-1 . . . 182-N, respectively. The DC energy sources 120-1 . . . 120-N, collectively referred to as DC sources 120, are generally renewable energy sources such as wind, solar, hydro, and the like, and provide DC power to the corresponding power conditioners 110. The power conditioners 110 generate commercial power grid compliant AC power from the received DC power. In certain embodiments, such as the embodiment described with respect to FIG. 1, each DC source 120 is a photovoltaic (PV) module, although in other embodiments one or more of the DC sources 120 may be other types of sources of DC energy (e.g., other types of renewable energy sources, a DC generator, or the like). In some alternative embodiments, the power conditioners 110 are AC-AC converters (such as AC-AC matrix converters), and the DC sources 120 are AC sources). In still other alternative embodiments, one or more the DER generators 182 are different types of distributed generators, such as internal-combustion generators fueled by gas, diesel, propane, or the like.

The power conditioners 110-N+1 . . . 110-N+M are coupled to energy storage devices 122-1 . . . 122-M, respectively, to form AC batteries 180-1 . . . 180-M, respectively. The energy storage devices 122-1 . . . 122-M, collectively referred to as energy storage devices 122, may be any type of suitable device for storing and subsequently delivering energy, such as batteries, flywheels, compressed air storage, hot water heaters, electric cars, or the like. When storing energy in the energy storage devices 122, the power conditioners 110-N+1 . . . 110-N+M convert AC power from the bus 170 to energy that is stored in the corresponding energy storage device 122-1 . . . 122-M. When energy from the energy storage devices 120 is discharging, the power conditioners 110-N+1 . . . 110-N+M convert energy from the corresponding energy storage devices 122-1 . . . 122-M to commercial power grid compliant AC power that is coupled to the bus 170.

Each of the power conditioners 110 measures one or more associated energy levels, such as the amount of energy it is receiving from a corresponding DC source 120 or energy storage device 122, the amount of energy it is generating from the received DC energy, the amount of energy it is receiving from the bus 170 for charging a corresponding energy storage device 122, the amount of energy it is coupling to a corresponding energy storage device 122, and the like. Such energy measurements may be continuously obtained (in near real-time), or periodically obtained.

In other embodiments, the DER 118 may have different numbers of DER generators 182 and/or AC batteries 180, for example only a single DER generator 182 and/or a single AC battery 180. In some alternative embodiments, multiple DC sources 112 are coupled to a single power conditioner 110 (e.g., a single, centralized power conditioner) rather than in a one-to-one correspondence. In one or more alternative embodiments, the power conditioners 110 are DC-DC converters that generate DC power and couple the generated power to a DC bus (i.e., the bus 170 is a DC bus in such embodiments); in such embodiments, the power conditioners 110-N+1 through 110-N+M also receive power from the DC bus and convert the received power to energy that is then stored in the corresponding energy storage device 122.

The DER controller 116 is coupled to the load center 112 for communicating with the power conditioners 110 using power line communications (PLC), although other types of wired and/or wireless techniques may additionally or alternatively be used. The DER controller 116 may provide operative control of the DER 118 (e.g., sending control and command instructions to the power conditioners 110) and/or may receive data or information (e.g., measured energy data) from the DER 118. For example, the DER controller 116 may be a gateway that receives data (e.g., alarms, messages, operating data and the like) from the power conditioners 110 and communicates the data and/or other information to a remote device or system, such as a master controller 128 described below. The DER controller 116 may also send control signals to the power conditioners 110, such as control signals generated by the DER controller 116 or sent to the DER controller 116 by the master controller 128.

The DER controller 116 is further communicatively coupled to the master controller 128 via a communications network 126 (e.g., the Internet) for sending information to and/or receiving information from the master controller 128. The DER controller 116 may utilize wired and/or wireless techniques for coupling to the communications network 126; in some embodiments, the DER controller 116 may be wirelessly coupled to the communications network 126 via a commercially available router.

The system 100 comprises a plurality of energy sources (e.g., the DER generators 182, the discharging AC batteries 180, and the power grid 124) and a plurality of energy recipients or sinks (e.g., the loads 114, the charging AC batteries 180, and the power grid 124 when excess energy generated by the DER 118 is fed back to it) among which energy flows at varying levels over time. For example, energy received by the loads 114 can come from the power grid 124, from the DER generators 182, and/or from the AC batteries 180 if they are sufficiently charged. Energy generated by the DC sources 120 can be used by the loads 114 (which may be also be referred to as the home 114), to charge the energy storage devices 122 if they are not already fully charged, and/or coupled back to the grid 124.

In accordance with embodiments of the present invention, one or more readily-understandable visualizations of various energy flows between one or more energy sources and one or more energy sinks is provided as described herein. A user may access, for example via a conventional web browser, a website 192 supported by the master controller 128 (or a server having access to the master controller data) to obtain an energy flow display based on the energy flow data. Additionally, a multitude of users may access one or more of such displays via a password protected portal.

During operation of the DER 118, the DER controller 116 periodically reports a plurality of energy flow measurements (which also may be referred to as energy time series information) to the master controller 128, such as production by the DC sources 120 (which may also be referred to as the “solar production” or “PV production”), total consumption, discharge of the AC batteries 180, and AC battery charge. In other embodiments, other energy flow measurements may be additionally or alternatively used. Generally, the energy flow measurements have granularity on the order of 5-15 minutes, although in other embodiments other levels of granularity may be used. The energy flow measurements are used to provide one or more visual depictions of various energy flows as described in detail below. For a particular time interval, for example from 15 minutes on up, energy flow information can be presented in a readily understandable format to visualize energy flows between one or more energy sources and one or more energy sinks, such as PV production flow (e.g., how much of the energy produced by the DC sources 120 is going to each of the loads 114, the energy storage devices 180, and the grid 124) and consumption flow (e.g., how much of the energy consumed by the loads 114 is coming from each of the DC sources 120, the energy storage devices 180, and the grid 124).

In order to provide a visualization of such complex energy flow metrics, a plurality of different energy flow values are computed using the obtained energy measurements and defined energy priority allocation rules as described in detail further below.

FIG. 2 is a block diagram of a power conditioner controller 140 in accordance with one or more embodiments of the present invention. The power conditioner controller 140 comprises at least one central processing unit (CPU) 202 coupled to each of a memory 204, support circuits 206 (i.e., well known circuits used to promote functionality of the CPU 202, such as a cache, power supplies, clock circuits, buses, input/output (I/O) circuits, and the like), and a transceiver 208 that is communicatively coupled to the DER controller 116.

The CPU 202 may comprise one or more conventionally available microprocessors or microcontrollers. The power conditioner controller 140 may be implemented using a general purpose computer that, when executing particular software, becomes a specific purpose computer for performing various embodiments of the present invention. In one or more embodiments, the CPU 202 may be a microcontroller comprising internal memory for storing controller firmware that, when executed, provides the controller functionality described herein. In some embodiments, the power conditioner controller 140 may additionally or alternatively comprise one or more application specific integrated circuits (ASIC) for performing one or more of the functions described herein.

The memory 204 may comprise random access memory, read only memory, removable disk memory, flash memory, and various combinations of these types of memory; the memory 204 is sometimes referred to as main memory and may, in part, be used as cache memory or buffer memory. The memory 204 generally stores an operating system (OS) 210, such as one of a number of available operating systems for microcontrollers and/or microprocessors (e.g., LINUX, Real-Time Operating System (RTOS), and the like). The memory 204 further stores non-transient processor-executable instructions and/or data that may be executed by and/or used by the CPU 202. These processor-executable instructions may comprise firmware, software, and the like, or some combination thereof.

The memory 204 stores various forms of application software, such as a power conversion control module 212 for controlling power conversion by the power conditioners 110 and a data measurement module 214 for measuring various data associated with the power conditioner 110, such as energy flows to and/or from the power conditioner 110. The memory 204 additionally stores a database 216 for storing data related to power conversion and/or the present invention. In various embodiments, the power conversion control module 212 and the database 216, or portions thereof, may be implemented in software, firmware, hardware, or a combination thereof.

FIG. 3 is a block diagram of a DER controller 116 in accordance with one or more embodiments of the present invention. The DER controller 116 comprises a DER transceiver 302, a master controller transceiver 316, support circuits 306, and a memory 308 each coupled to at least one CPU 304. The CPU 304 may comprise one or more conventionally available microprocessors; additionally or alternatively, the CPU 304 may include one or more application specific integrated circuits (ASICs). In some embodiments, the CPU 304 may be a microcontroller comprising internal memory for storing controller firmware that, when executed, provides the controller functionality herein. The DER controller 116 may be implemented using a general purpose computer that, when executing particular software, becomes a specific purpose computer for performing various embodiments of the present invention.

The support circuits 306 are well known circuits used to promote functionality of the CPU 304. Such circuits include, but are not limited to, a cache, power supplies, clock circuits, buses, network cards, input/output (I/O) circuits, and the like.

The DER transceiver 302 is communicatively coupled to the power conditioners 110, and the master controller transceiver 316 is communicatively coupled to the master controller 128 via the communications network 126. The transceivers 302 and 316 may utilize wireless (e.g., based on standards such as IEEE 802.11, Zigbee, Z-wave, or the like) and/or wired (e.g., PLC) communication techniques for such communication, for example a WI-FI or WI-MAX modem, 3G modem, cable modem, Digital Subscriber Line (DSL), fiber optic, or similar type of technology.

The memory 308 may comprise random access memory, read only memory, removable disk memory, flash memory, and various combinations of these types of memory. The memory 308 is sometimes referred to as main memory and may, in part, be used as cache memory or buffer memory. The memory 308 generally stores an operating system (OS) 310 of the DER controller 116. The OS 310 may be one of a number of available operating systems for microcontrollers and/or microprocessors.

The memory 308 stores various forms of application software, such as a local DER control module 312 for providing operative control of the DER 118 (e.g., providing command instructions to the power conditioners 110 regarding power production levels), and a data module 314 for obtaining various data from the system 100, such as measured energy flow data from the DER 118 and the meter 190. The data module 314 may additionally perform processing on received data as necessary, such as performing arithmetic computations.

The memory 308 additionally stores a database 318 for storing data, such as data related to the DER 118, one or more algorithms for operating on data, energy priority allocation rules, and the like. In various embodiments, the local DER control module 312, the data module 314, and the database 318, or portions thereof, may be implemented in software, firmware, hardware, or a combination thereof.

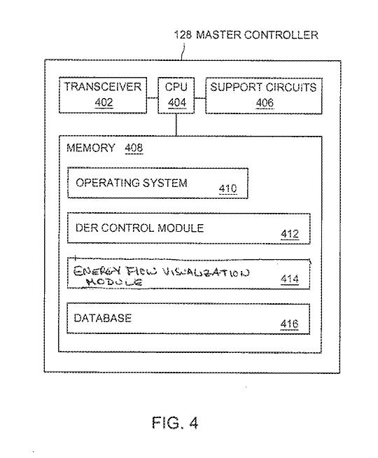

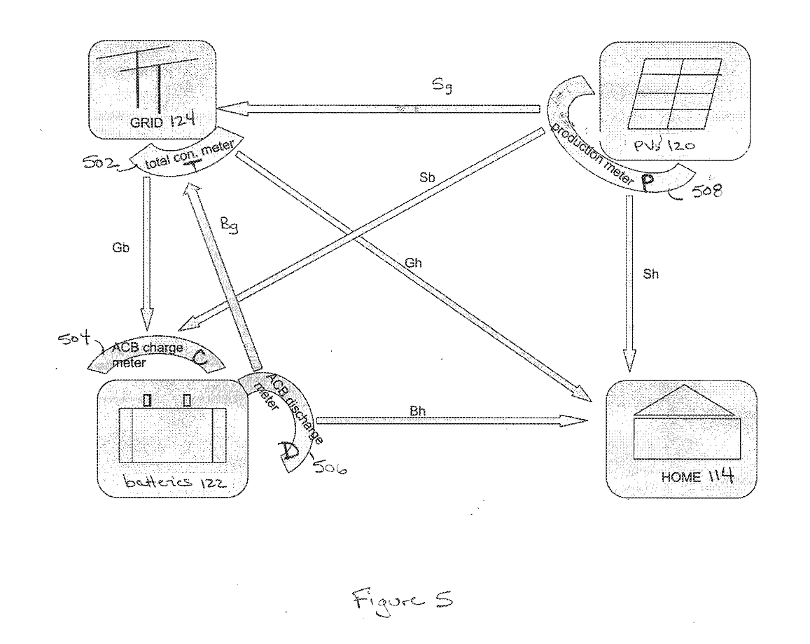

FIG. 4 is a block diagram of a master controller 128 in accordance with one or more embodiments of the present invention. The master controller 128 comprises a transceiver 402, support circuits 406, and a memory 408 each coupled to at least one central processing unit (CPU) 404. The CPU 404 may comprise one or more conventionally available microprocessors; additionally or alternatively, the CPU 404 may include one or more application specific integrated circuits (ASICs). In some embodiments, the CPU 404 may be a microcontroller comprising internal memory for storing controller firmware that, when executed, provides the controller functionality herein. The master controller 128 may be implemented using a general purpose computer that, when executing particular software, becomes a specific purpose computer for performing various embodiments of the present invention.

The support circuits 406 are well known circuits used to promote functionality of the CPU 404. Such circuits include, but are not limited to, a cache, power supplies, clock circuits, buses, network cards, input/output (I/O) circuits, and the like.

The transceiver 402 is communicatively coupled to the DER controller 116 via the communications network 126. The transceiver 402 may utilize wireless (e.g., based on standards such as IEEE 802.11, Zigbee, Z-wave, or the like) and/or wired communication techniques for such communication, for example a WI-FI or WI-MAX modem, 3G modem, cable modem, Digital Subscriber Line (DSL), fiber optic, PLC, or similar type of technology.

The memory 408 may comprise random access memory, read only memory, removable disk memory, flash memory, and various combinations of these types of memory. The memory 408 is sometimes referred to as main memory and may, in part, be used as cache memory or buffer memory. The memory 408 generally stores an operating system (OS) 410 of the master controller 128. The OS 410 may be one of a number of available operating systems for microcontrollers and/or microprocessors.

The memory 408 stores various forms of application software, such as a DER control module 412 for providing operative control of the DER 118 (e.g., providing command instructions to the DER controller 116 regarding power production levels) and, in some embodiments, additional DERs. The memory 408 further comprises an energy flow visualization module 414 computing various energy flows and generating one or more visualizations of energy flows based on the computed energy flows. Further detail on the functionality provided by the energy flow visualization module 414 is described below with respect to FIG. 8.

The memory 408 additionally stores a database 416 for storing data, such as data related to the operation of the DER 118, measured energy flow data, computed energy flow data, energy priority allocation rules, one or more algorithms for determining computed energy flows, and the like. In various embodiments, the DER control module 412, the energy flow visualization module 414, and the database 416, or portions thereof, may be implemented in software, firmware, hardware, or a combination thereof.

In one or more alternative embodiments, some or all of the energy flow computations, and/or the energy flow visualization, may additionally or alternatively be done by the DER controller 116.

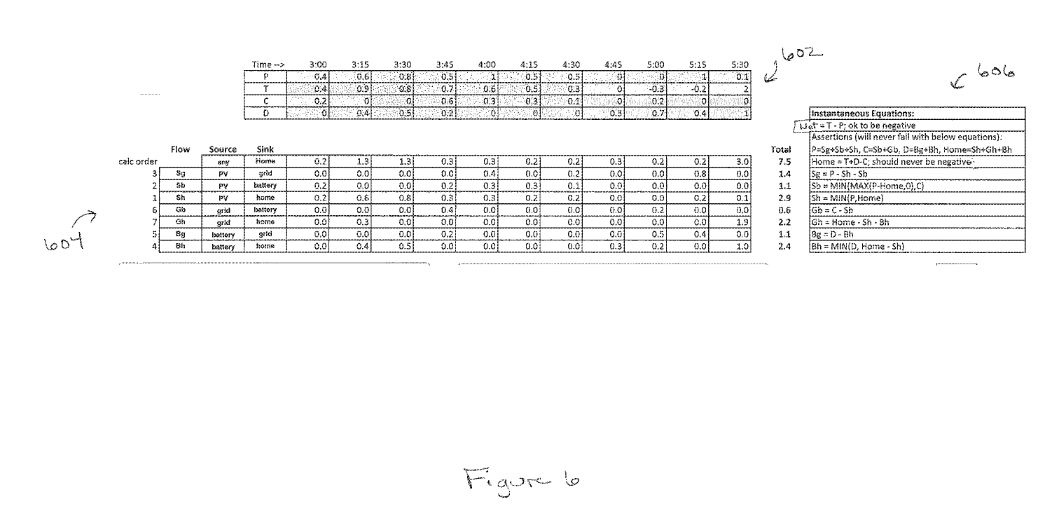

FIG. 5 is a block diagram depicting energy sources and sinks of the system 100 and corresponding computed energy flows in accordance with one or more embodiments of the present invention. As shown in FIG. 5, energy flow metering points 508, 502, 504 and 506 are depicted that correspond to measured energy flows P=production by the DC sources 120 (which may also be referred to as the PVs 120 for the embodiment described here), T=total consumption, C=charge for the energy storage devices 122 (which may also be referred to as batteries 122 for the embodiment described here), and D=discharge for the batteries 122, respectively. In some other embodiments, the measured energy flow P may be a measurement of production by the DER generators 110 (for example, the energy generated by the power conditioners 110 from the corresponding DC sources 120). The measured energy flow data is used by the DER controller 116 and/or the master controller 128 for determining the computed energy flows for providing the energy flow visualizations.

The computed energy flows determined using the measured energy flows are depicted as solar-to-grid (Sg) from the PVs 120 to the grid 124; solar-to-batteries (Sb) from the PVs 120 to the batteries 122; solar-to-home (Sh) from the PVs 120 to the loads 114 (also referred to as the home 114); batteries-to-home (Bh) from the batteries 122 to the home 114; battery-to-grid (Bg) from the batteries 122 to the grid 124; grid-to-home (Gh) from the grid 124 to the home 114; and grid-to-batteries (Gb) from the grid 124 to the batteries 122. Generally, the computed energy flow Bg is equal to zero, although in certain embodiments it may be non-zero, for example during an emergency when energy from the AC batteries 180 is used to support the grid 124.

In some embodiments, one or more of the metering points 502, 504, 506 and 508 are physical meters that measure the corresponding energy flows and communicate the measured data by any suitable wired and/or wireless technique to another component for processing (e.g., the master controller 128).

In other embodiments, one or more of the metering points 502, 504, 506 and 508 represents a combination of measured energy data obtained within the system 100. For example, in some embodiments the metering point 508 represents the sum of energy measurements from each of the DER generators 182 over a particular time period; the metering point 506 represents the sum of energy measurements from each of the discharging AC batteries 180 over a particular time period; and the metering point 504 represents the sum of energy measurements from each of the charging AC batteries 180 over a particular time period. The resulting energy flow measurements P, D and C, respectively, may be computed by the DER controller 116 from the individual energy measurements from the DER 118 and sent to the master controller 128; alternatively, they may be computed by the master controller 128.

In one or more embodiments, the metering point 502 represents a net energy flow measurement from the grid 124 (Net) over a particular time period, less the PV production P over that same time period. The net energy flow measurement Net may, in some embodiments, be provided by the meter 190.

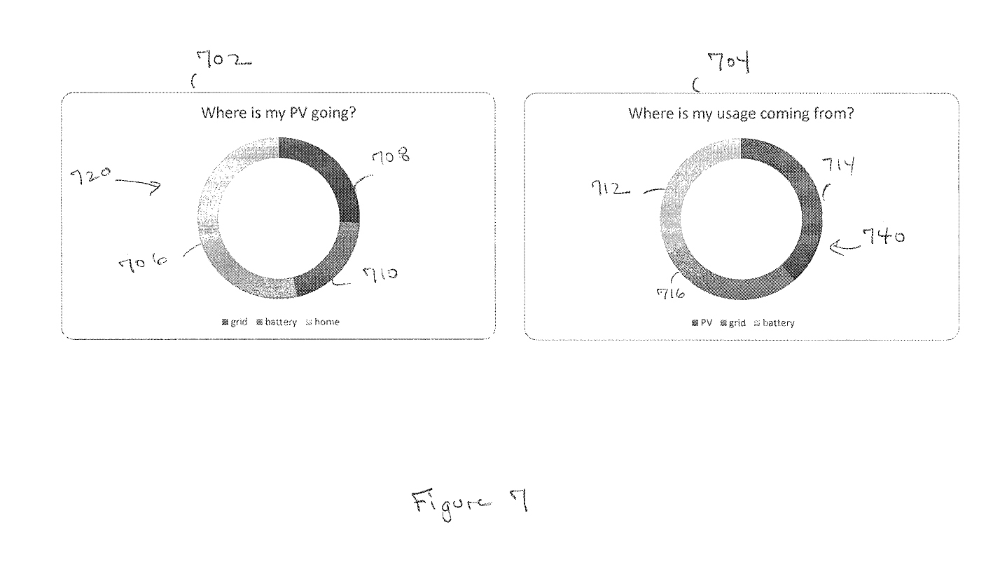

FIG. 6 is a plurality of tables for a rolling time series in accordance with one or more embodiments of the present invention. Tables 602, 604, and 606 are shown in FIG. 6.

The table 602 shows a time-series of energy flow measurements that correspond to the four metering points in FIG. 5—metering point 508 for the measured energy flow P; metering point 502 for the measured energy flow T; metering point 504 for the measured energy flow C, and metering point 506 for the measured energy flow D. As shown in table 602, the measurements are provided in a 15-minute time series on a particular day from 3:00 pm-5:30 pm, although in other embodiments measurements may be in different time increments and/or over different times periods.

The table 604 shows the values for the computed energy flows Sg, Sb, Sh, Gb, Gh, Bg, and Bh for each of the time intervals of the table 602. The order of calculations for the computed energy flows, based on the assigned priorities, is shown under the heading “calc order”. The particular computed energy flows are listed under the heading “flow”, and the corresponding computed energy flow sources and sinks are listed under the headings “source” and “sink”, respectively.

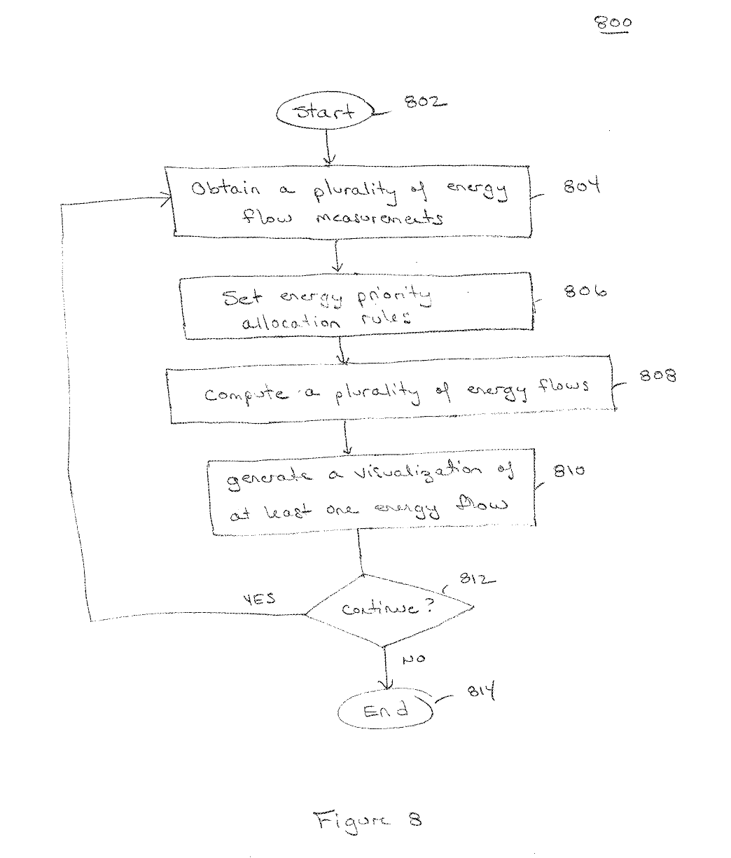

The table 606 shows the equations used for determining each of the computed energy flows Sg, Sb, Sh, Gb, Gh, Bg, and Bh, where Net may be measured by the meter 190). The computed energy flows are used to derive the visual depictions described below with respect to FIG. 7.

Although the embodiment described with respect to FIG. 6 is directed to energy flow, in other embodiments the flows computed and the resulting visualizations may pertain to other parameters related to the DER 118 such as power or current.

FIG. 7 is a representation of displays 702 and 704 for energy flow visualization for the system 100 in accordance with one or more embodiments of the present invention. In the embodiment shown in FIG. 7, the DC energy sources 120 are PV modules and the energy storage devices 122 are batteries, although in other embodiments other types of DC energy sources 120 may be used (such as other types of renewable energy sources) and/or other types of energy storage devices 120 may be used.

The display 702 comprises a display image 720 which visually depicts the computed energy flows during a particular time period from the DER generators 182 to each of the grid 124 (i.e., Sg), the AC batteries 182 (i.e., Sb), and the home 114 (i.e., Sh) as shown by display image portions 708, 710, and 706, respectively. The display image portions 708, 710 and 706 may be visually differentiated from one another by any suitable technique or combination of such techniques, such as color, hue, display intensity, cross-hatching, and the like. In some other embodiments, energy flows from other energy sources may additionally or alternatively be depicted, such as diesel generators. In certain embodiments, energy flow to other types of energy sinks may be depicted, and/or the energy flows to various energy sinks may be depicted in more granularity (e.g., energy flow to each of specific loads, energy flow to each AC battery 180, and the like).

The display image 720 is displayed on a display; for example, the display image 720 may be displayed on a user's computer via a conventional web browser. Although the display image 720 is annularly shaped, in other embodiments other types of displays may be used to provide the energy flow visualizations, such as pie charts, bar charts, and the like.

The display 704 comprises a display image 740 which visually depicts the computed energy flows during a particular time period to the loads 114 from each of the DER generators 182 (i.e., Sh), the grid 124 (Gh), and the AC batteries 182 (i.e., Bh) as shown by display image portions 714, 716, and 712, respectively. The display image portions 714, 716, and 712 may be visually differentiated from one another by any suitable technique or combination of such techniques, such as color, display intensity, cross-hatching, and the like. In some other embodiments, energy flows from other energy sources may additionally or alternatively be depicted, such as diesel generators, and/or the energy flows from various energy sources may be depicted in more granularity (e.g., energy flow from each AC battery 180, energy flow from each DER generator 182, and the like).

The display image 740 is displayed on a display; for example, the display image 740 may be displayed on a user's computer via a conventional web browser. Although the display image 740 is annularly shaped, in other embodiments other types of displays may be used to provide the energy flow visualizations, such as pie charts, bar charts, and the like.

FIG. 8 is a flow diagram of a method 800 for energy flow visualization in accordance with one or more embodiments of the present invention. The energy flow visualization described below pertains to a system having a distributed energy resource (DER), such as the system 100 comprising the DER 118. In other embodiments, the energy visualization may pertain to other types of systems having other types of DERs.

In one or more embodiments, the method 800 is an implementation of the master controller's energy flow visualization module 414 described above. In other embodiments, the module of the DER controller 116 may perform the method 800. In still other embodiments, the method 800 may in part be performed by master controller's energy flow visualization module 414 and in part by a module of the DER controller 116. In certain embodiments, a computer readable medium comprises a program that, when executed by a processor, performs the method 800 that is described in detail below.

The method 800 begins at step 802 and proceeds to step 804. At step 804, a plurality of energy flow measurements are obtained. The energy flow measurements T, C, D and P are obtained with respect to the metering points 502, 504, 506 and 508, respectively, described above with respect to FIG. 5. The energy flow measurements are periodically obtained, for example on the order of every 5 to 15 minutes.

In some embodiments, one or more of the metering points 502, 504, 506 and 508 are physical meters that measure the corresponding energy flows and communicate the measured data by any suitable wired and/or wireless technique to a central location for processing (e.g., the master controller 128). In other embodiments, one or more of the metering points 502, 504, 506 and 508 represents a combination of measured energy data obtained within the system 100. For example, in some embodiments, the energy flow measurement T is equal to the net energy flow measurement Net (e.g., obtained from the meter 190), less the PV production P; the PV energy production P is equal to the sum of the measured energy from each of the DER generators 182 as measured by the corresponding power conditioner 110; the battery charge energy C is equal to the sum of energy consumed to charge each of the energy storage devices 122 as measured by the corresponding power conditioner 110; and the battery discharge energy D is equal to the sum of energy discharged by each of the energy storage devices 122 as measured by the corresponding power conditioner 110.

The method 800 proceeds to step 806. At step 806, energy priority allocation rules are set. The energy priority allocation rules define the priorities for the various energy sinks to receive generated energy from the DER energy sources and the power grid 124. In certain embodiments, the energy priority allocation for energy derived from the PV modules 120 is defined as to the home 114 first, followed by the AC batteries 180 and lastly the power grid 124; the energy priority allocation for energy output from the AC batteries 180 is defined as to the home 114 first, followed by the grid 124; and the energy priority allocation for energy from the power grid 124 is whatever in the system 100 is not addressed by the DER. In other embodiments, the priorities of recipients of energy from the DER energy sources may be defined differently and/or the priorities of recipients of energy from the grid 124 are also defined.

The method 800 proceeds to step 808, where a plurality of energy flows between energy sources and energy sinks in the system 100 is computed. The energy flows Sg, Sb, Sh, Gh, Gb, Bg and Bh are computed using the measured energy flows T, P, C and D and the energy priority allocation rules as shown in the table 606 previously described with respect to FIG. 6. The energy flows Sg, Sb, Sh, Gh, Gb, Bg and Bh are computed in the order as shown in the table 604, also previously described with respect to FIG. 6.

At step 810, one or more energy flow visualizations are generated for at least one of the computed energy flows. Various energy flow visualizations may be generated, including visualizations depicting energy distributed from one or more energy sources to one or more energy sinks (e.g., as depicted in the display image 702 previously described with respect to FIG. 7), visualizations depicting energy usage from one or more energy sources (e.g., as depicted in the display image 702 previously described with respect to FIG. 7). In some embodiments, relative amounts of computed energy flows may be depicted; in other embodiments, absolute amounts of computed energy flows may additionally or alternatively be depicted.

The energy flow visualizations depicted may be determined by user selections, where a user may select one or more types of visualizations to be displayed as well as a time period over which each visualization applies. Additionally or alternatively, one or more energy flow visualizations may be periodically displayed; for example, an energy flow visualization may be shown every hour depicting the data from the last hour.

The method 800 proceeds from step 810 to step 812, where a decision is made whether to continue. If the result of the decision is yes, the method 800 returns to step 804. In some embodiments, the method 800 automatically repeats; in one or more of such embodiments, the same energy priority allocation rules are utilized during each execution of the method 800.

If the result of the decision at step 812 is no, the method 800 proceeds to step 814 where it ends.

In some alternative embodiments, one or more of the steps of the method 800 may be done in an order different from that described above; for example, the step 806 may be performed before the step 804.

The foregoing description of embodiments of the invention comprises a number of elements, devices, circuits and/or assemblies that perform various functions as described. These elements, devices, circuits, and/or assemblies are exemplary implementations of means for performing their respectively described functions.

While the foregoing is directed to embodiments of the present invention, other and further embodiments of the invention may be devised without departing from the basic scope thereof, and the scope thereof is defined by the claims that follow.

1. A method for visualizing energy flows, comprising:
obtaining a plurality of measured energy flow values for a plurality of energy flows between a plurality of energy sources and a plurality of energy sinks, wherein at least one of measured energy flow value of the plurality of measured energy flow values is a measurement of energy flow from an energy source of the plurality of energy sources to two or more energy sinks of the plurality of energy sinks;
computing a plurality of energy flow values based on the measured energy flow values and a set of energy priority allocation rules, wherein each computed energy flow value of the plurality of energy flow values represents energy flow between an energy source of the plurality of energy sources and an energy sink of the plurality of energy sinks; and
generating a display image representing at least one computed energy flow value of the plurality of energy flow values.

2. The method of claim 1, wherein the plurality of measured energy flow values comprises (i) a measurement of energy production by at least one distributed energy resource (DER) generator, (ii) a measurement of total consumption from a power grid, (iii) a measurement of charge for at least one energy storage device of the DER that is charging, and (iv) a measurement of discharge for at least one energy storage device of the DER that is discharging.

3. The method of claim 1, wherein the plurality of computed energy flow values comprises (i) a value representing energy flow from at least one distributed energy resource (DER) generator to a power grid; (ii) a value representing energy flow from the at least one DER generator to a first at least one energy storage device of the DER, (iii) a value representing energy flow from the at least one DER generator to at least one load, (iv) a value representing energy flow from a second at least one energy storage device to the at least one load, (v) a value representing energy flow from the second at least one energy storage device to the power grid, (vi) a value representing energy flow from the power grid to the at least one load, and (vii) a value representing energy flow from the power grid to the first at least one energy storage device.

4. The method of claim 1, wherein the set of energy priority allocation rules defines a priority for each energy sink of the plurality of energy sinks to receive energy generated by the plurality of energy sources.

5. The method of claim 4, wherein the set of energy priority allocation rules defines priorities for (i) energy derived from at least one distributed energy resource (DER) generator to be used first by at least one load, followed by a first at least one energy storage device of the DER, followed by a power grid, and (ii) energy derived from a second at least one energy storage device of the DER to be used first by the at least one load, followed by the power grid.

6. The method of claim 1, wherein the display image depicts amounts of energy flow from at least one an energy source of the plurality of energy sources to each of at least two energy sinks of the plurality of energy sinks.

7. The method of claim 1, wherein the display image depicts amounts of energy flow to at least one an energy sink of the plurality of energy sinks from each of at least two energy sources of the plurality of energy sources.

8. Apparatus for visualizing energy flows, comprising:
a controller comprising at least one processor and an energy flow visualization module for:
obtaining a plurality of measured energy flow values for a plurality of energy flows between a plurality of energy sources and a plurality of energy sinks, wherein at least one of measured energy flow value of the plurality of measured energy flow values is a measurement of energy flow from an energy source of the plurality of energy sources to two or more energy sinks of the plurality of energy sinks;
computing a plurality of energy flow values based on the measured energy flow values and a set of energy priority allocation rules, wherein each computed energy flow value of the plurality of energy flow values represents energy flow between an energy source of the plurality of energy sources and an energy sink of the plurality of energy sinks; and
generating a display image representing at least one computed energy flow value of the plurality of energy flow values.

9. The apparatus of claim 8, wherein the plurality of measured energy flow values comprises (i) a measurement of energy production by at least one distributed energy resource (DER) generator, (ii) a measurement of total consumption from a power grid, (iii) a measurement of charge for at least one energy storage device of the DER that is charging, and (iv) a measurement of discharge for at least one energy storage device of the DER that is discharging.

10. The apparatus of claim 8, wherein the plurality of computed energy flow values comprises (i) a value representing energy flow from at least one distributed energy resource (DER) generator to a power grid; (ii) a value representing energy flow from the at least one DER generator to a first at least one energy storage device of the DER, (iii) a value representing energy flow from the at least one DER generator to at least one load, (iv) a value representing energy flow from a second at least one energy storage device to the at least one load, (v) a value representing energy flow from the second at least one energy storage device to the power grid, (vi) a value representing energy flow from the power grid to the at least one load, and (vii) a value representing energy flow from the power grid to the first at least one energy storage device.

11. The apparatus of claim 8, wherein the set of energy priority allocation rules defines a priority for each energy sink of the plurality of energy sinks to receive energy generated by the plurality of energy sources.

12. The apparatus of claim 11, wherein the set of energy priority allocation rules defines priorities for (i) energy derived from at least one distributed energy resource (DER) generator to be used first by at least one load, followed by a first at least one energy storage device of the DER, followed by a power grid, and (ii) energy derived from a second at least one energy storage device of the DER to be used first by the at least one load, followed by the power grid.

13. The apparatus of claim 8, wherein the display image depicts amounts of energy flow from at least one an energy source of the plurality of energy sources to each of at least two energy sinks of the plurality of energy sinks.

14. The apparatus of claim 8, wherein the display image depicts amounts of energy flow to at least one energy sink of the plurality of energy sinks from each of at least two energy sources of the plurality of energy sources

15. A computer readable medium comprising a program that, when executed by a processor, performs a method for visualizing energy flows, the method comprising:
obtaining a plurality of measured energy flow values for a plurality of energy flows between a plurality of energy sources and a plurality of energy sinks, wherein at least one of measured energy flow value of the plurality of measured energy flow values is a measurement of energy flow from an energy source of the plurality of energy sources to two or more energy sinks of the plurality of energy sinks;
computing a plurality of energy flow values based on the measured energy flow values and a set of energy priority allocation rules, wherein each computed energy flow value of the plurality of energy flow values represents energy flow between an energy source of the plurality of energy sources and an energy sink of the plurality of energy sinks; and
generating a display image representing at least one computed energy flow value of the plurality of energy flow values.

16. The computer readable medium of claim 15, wherein the plurality of measured energy flow values comprises (i) a measurement of energy production by at least one distributed energy resource (DER) generator, (ii) a measurement of total consumption from a power grid, (iii) a measurement of charge for at least one energy storage device of the DER that is charging, and (iv) a measurement of discharge for at least one energy storage device of the DER that is discharging.

17. The computer readable medium of claim 15, wherein the plurality of computed energy flow values comprises (i) a value representing energy flow from at least one distributed energy resource (DER) generator to a power grid; (ii) a value representing energy flow from the at least one DER generator to a first at least one energy storage device of the DER, (iii) a value representing energy flow from the at least one DER generator to at least one load, (iv) a value representing energy flow from a second at least one energy storage device to the at least one load, (v) a value representing energy flow from the second at least one energy storage device to the power grid, (vi) a value representing energy flow from the power grid to the at least one load, and (vii) a value representing energy flow from the power grid to the first at least one energy storage device.

18. The computer readable medium of claim 15, wherein the set of energy priority allocation rules defines priorities for (i) energy derived from at least one distributed energy resource (DER) generator to be used first by at least one load, followed by a first at least one energy storage device of the DER, followed by a power grid, and (ii) energy derived from a second at least one energy storage device of the DER to be used first by the at least one load, followed by the power grid.

19. The computer readable medium of claim 15, wherein the display image depicts amounts of energy flow from at least one an energy source of the plurality of energy sources to each of at least two energy sinks of the plurality of energy sinks.

20. The computer readable medium of claim 15, wherein the display image depicts amounts of energy flow to at least one an energy sink of the plurality of energy sinks from each of at least two energy sources of the plurality of energy sources.
